(19) United States
(12) Patent Application Publication
(10) Pub. No.: US 2023/0395708 A1
(43) Pub. Date: Dec. 7, 2023

(54) TRANSISTOR HAVING HIGH ELECTRON MOBILITY (HEMT), TRANSISTOR ASSEMBLY, METHOD FOR CONTROLLING AN HEMT, AND METHOD FOR PRODUCING AN HEMT

(71) Applicant: Fraunhofer-Gesellschaft zur Förderung der angewandten Forschung e.V., München (DE)

(72) Inventors: Holger KAPELS, Itzehoe (DE); Simon FICHTNER, Itzehoe (DE); Fabian LOFINK, Itzehoe (DE); Bernhard WAGNER, Itzehoe (DE)

(21) Appl. No.: 18/455,197

(22) Filed: Aug. 24, 2023

Related U.S. Application Data
(63) Continuation of application No. PCT/EP2022/054576, filed on Feb. 23, 2022.

(30) Foreign Application Priority Data
Feb. 25, 2021 (DE) 10 2021 201 791.6

(51) Int. Cl. H01L 29/778; H01L 29/20; H01L 29/66

(52) U.S. Cl. CPC H01L 29/7787; H01L 29/2003; H01L 29/66462

(57) ABSTRACT

A transistor having high electron mobility (HEMT) having a first layer and a second layer is described. The first layer has a first material made of a first nitride compound. The first nitride compound has a group III element. The second layer has a second material made of a second nitride compound. The second nitride compound has a group III element. A main surface of the second layer is arranged opposite a main surface of the first layer, such that a charge zone forms along the main surface of the second layer. The HEMT further has a gate electrode, which is arranged opposite the second layer, at least in regions, such that the second layer is arranged between the first layer and the gate electrode. Furthermore, the HEMT has a third layer, which is arranged between the gate electrode and the second layer. The third layer has a ferroelectric third material made of a third nitride compound, or a ferroelectric third material made of an oxide compound which contains zinc.

### CROSS-REFERENCE TO RELATED APPLICATIONS

This application is a continuation of copending International Application No. PCT/EP2022/054576, filed Feb. 23, 2022, which is incorporated herein by reference in its entirety, and additionally claims priority from German Application No. 10 2021 201 791.6, filed Feb. 25, 2021, which is also incorporated herein by reference in its entirety.

### TECHNICAL FIELD

Examples of the present invention relate to a transistor having high electron mobility (High-Electron-Mobility-Transistor (HEMT)). Further examples relate to a transistor assembly. Further examples relate to methods for controlling an HEMT. Further examples relate to methods for producing an HEMT.

### BACKGROUND OF THE INVENTION

HEMT component structures typically have a two-dimensional electron gas (2DEG), which forms for example an AlGaN/GaN structure at the boundary surface during the production process. Due to the permanent development of a conductive 2DEG at the boundary surface between two III-N-based layers, the HEMTs based thereon are permanently in the on-state (normally-on structure), without the additional application of a gate voltage. This firstly has disadvantages under safety aspects (the components are always on, even in the event of a failure of the gate voltage supply), and in addition it makes it more difficult to produce integrated logic gates based on this technology.

However, for widespread use, e.g. in power electronics circuits, in contrast to said normally-on structure, normally-off structures are required, the 2DEG of which is interrupted without an applied gate voltage, or conducts only a small cutoff current. Today, this function is pursued via various alternative approaches, such as via Schottky gate structures, recess gate structures, or fluorine ion implantation below the gate. However, all these variants have only very low threshold voltages Vth in the range of less than or close to 1 V. Higher threshold voltages can be achieved by means of a p-doped AlGaN gate. However, this solution has the disadvantage that, depending on the effect of the gate contact metallization as a Schottky or ohmic contact, high gate leakage currents may arise. If a Schottky contact is formed, then the depletion zone resulting in the p-GaN reduces the direct control of the 2DEG over the gate potential.

Alternatively, III-N heterostructure-based normally-off HEMTs can also be achieved by the use of ferroelectric (FE) materials. Analogously to the concept of the FE field-effect transistor (FE-FET), e.g. for storage applications, a type of variable voltage offset can be integrated in the gate stack, by means of the charges that can be shifted in the ferroelectric material. As a result, the gate voltage can be shifted in such a way that the threshold voltage is above 0 V and the transistor is thus in a non-conductive state, even without an applied gate voltage. This approach was hitherto implemented in the case of established oxide-based ferroelectrics, for example LiNbO3, Pb(Zr,Ti)O3, BaTiO3, HfO2 compounds [Hao12, Zhu18, Li19, Hao17, Yan17, Teo19]. For example, US 2019/0115445 A1 describes the use of a ferroelectric material in the gate stack, having a maximum thickness of tcap/2*α*εcap, in order to achieve high limit frequencies despite higher cap-layer thicknesses. CN107316901A describes an FE-HEMT comprising HfO₂ as the FE gate. CN107369704A describes an FE-HEMT comprising a multilayer gate structure having a gate dielectric made of AlN or Al₂O₃, plus one ferroelectric HfZrO layer. CN102299576B uses LiNbO₃ or LiTaO₃ as alternative FE materials. TW201906163A describes a component comprising gate electrodes which interrupt the 2DEG and contain a ferroelectric dielectric, wherein the electrodes can be operated as a back gate. JP2010206048A also describes an HEMT comprising an oxidic FE gate.

An HEMT of which the threshold voltage can be set in a stable manner over a wide range would be desirable.

### SUMMARY

According to an embodiment, a High-Electron-Mobility-Transistor, HEMT, may have: a first layer which has a first material made of a first nitride compound, wherein the first nitride compound has a group III element, a second layer which has a second material made of a second nitride compound, wherein the second nitride compound has a group III element, wherein a main surface of the second layer is arranged opposite a main surface of the first layer such that a charge zone forms along the main surface of the first layer, which provides a conduction channel in an enabled state of the HEMT, a gate electrode, which is arranged opposite the second layer, at least in regions, such that the second layer is arranged between the first layer and the gate electrode, a third layer, which is arranged between the gate electrode and the second layer, wherein the third layer has a ferroelectric third material made of a third nitride compound, or a ferroelectric third material made of an oxide compound which contains zinc, the third material containing a transition metal.

Another embodiment may have a transistor assembly, having an inventive HEMT as mentioned above, and further having a control signal generator, wherein the control signal generator is configured to apply a voltage to the gate electrode in order to set a polarization direction in a region of the third layer that is opposite the gate electrode.

According to another embodiment, a method for controlling an inventive HEMT as mentioned above may have the step of: applying a voltage to the gate electrode in order to set a polarization direction and/or a degree of polarization of the third material, in order to set a threshold voltage of the HEMT, at which a conduction channel through the charge zone changes between an enabled state and a disabled state.

According to another embodiment, a method for producing an HEMT may have the steps of: providing a layer structure having a first layer, a second layer, and a third layer, which has a ferroelectric third material made of a third nitride compound, or has a ferroelectric third material made of an oxide compound, which contains zinc, has a third nitride compound, or a ferroelectric third material made of an oxide compound, which contains zinc, the third material containing a transition metal, such that the second layer is arranged between the first layer and the third layer, a main surface of the second layer is arranged opposite a main surface of the first layer, and a charge zone forms along the main surface of the first layer, which provides a conduction channel in an enabled state of the HEMT, applying a source contact and a drain contact in such a way that the charge zone is arranged electrically in series between the source contact and the drain contact, temperature treatment of the layer structure together with the source contact and the drain contact.

An example of the present invention provides an HEMT comprising a first layer and a second layer. The first layer comprises a first material made of a first nitride compound. The first nitride compound comprises a group III element. The second layer comprises a second material made of a second nitride compound. The second nitride compound comprises a group III element. A main surface of the second layer is arranged opposite a main surface of the first layer, such that a charge zone forms along the main surface of the second layer. The charge zone can for example denote a region around a local extremum of a potential profile perpendicular to the main surface of the first layer. For example, the charge zone can provide a conduction channel in an enabled state of the HEMT, and can be depleted in a disabled state of the HEMT. The HEMT further comprises a gate electrode, which is arranged opposite the second layer, at least in regions, such that the second layer is arranged between the first layer and the gate electrode. Furthermore, the HEMT comprises a third layer, which is arranged between the gate electrode and the second layer. The third layer comprises a ferroelectric third material made of a third nitride compound or of an oxide compound which contains zinc.

Ferroelectric materials made of a nitride compound or of an oxide compound comprising zinc can have a particularly high polarization. Examples of the present invention are based on the finding that these materials are thereby particularly well-suited for the implementation of an HEMT. The arrangement of the third layer relative to the second layer can cause the threshold voltage HEMT to be shifted, by a large amount, on account of the high polarization. Thus, an HEMT having a larger threshold voltage can be achieved, such that a larger working region is made possible. In particular, positive threshold voltages are also possible, even large positive threshold voltages, such that the HEMT is disabled when no voltage is applied to the gate electrode, and a leakage current is particularly small in this state. While oxidic ferroelectrics frequently have remanent polarizations in ranges of 1-40 μC/cm², in the case of the materials used according to the invention this value can be up to 100 μC/cm². The larger polarization has the advantage that a larger offset is applied to the gate electrode, and the component is thus closed better and also is more secure, since an on-state can be achieved only by high external currents. The inventors have further found that the polarization in the ferroelectric nitride compounds or oxide components or oxide is particularly stable. For example, these materials have a high Curie temperature. As a result, the polarization of the third layer is stable, even in the case of a high operating temperature. The maximum use temperature of these materials can be over 1000° C., and thus substantially higher than that of the oxidic ferroelectrics (maximum 350° C.). Thus, the HEMT according to the invention is, for example, particularly well suited for power electronics components, such as current converters. The high temperature stability also allows a high degree of flexibility in the selection of the production processes for the HEMT, for example by means of a gate-first process. It can furthermore be made possible to produce the HEMT by means of a process in which the gate electrode or the FE third layer are processed from the front side. Furthermore, the ferroelectric materials used in accordance with the invention can be based on purely pyroelectric materials, and thus have excellent polarization stability, and thus for example high long-term stability. This can prevent the transistor from unintentionally changing back into its initial state after the polarization has been set, and thus for example changing from a tensioned into a conductive state. In particular, the ferroelectric nitride compounds or oxide-zinc compounds have a higher use temperature and high long-term stability as oxidic ferroelectrics, while they at the same time use a comparatively low temperature budget for production. In particular embodiments in which the third material is made of the third nitride compound have the advantage compared with HEMTs comprising oxidic materials that a reaction of the oxidic material with the III-N structures to oxidic boundary surfaces can be prevented, which has a positive effect on the long-term stability of the ferroelectrics and of the transistor properties of the heterostructure.

In examples, the third material has a wurtzite crystal structure. Since a material having a wurtzite crystal structure is selected as the third material, the third layer can thus be produced particularly expediently in combination with the first layer, in the second layer. For example, a use of a material having a wurtzite structure (such as III-N semiconductors or ZnO) as the third material makes it possible to epitaxially deposit (e.g. deposit on one another) a layer sequence made of the first layer, the second layer and the ferroelectric third layer, in order to thereby achieve particularly good material properties, e.g. with respect to the defect structure density, in the ferroelectric part of the gate structure. It is thereby possible, for example, to obtain a boundary layer between the second layer and the third layer that is particularly low in defects. The possibility of epitaxially depositing the first, second and third layer furthermore allows for a simple production process.

In examples in which the third material comprises the third nitride compound, the third nitride compound comprises one or more group III elements. Group III nitride compounds are often semiconductor materials having a large bandgap, as a result of which the HEMT can be configured so as to be particularly low-loss. Furthermore, group III nitride compounds can have a high degree of polarization. Many group III nitrides have a wurtzite crystal structure, such that group III nitrides can combine the advantages of the wurtzite crystal structure with the advantages of a large bandgap and high polarization.

In examples, the one or more group III elements of the third nitride compound are one or more of Al, Ga, or In. These group III nitride compounds can have a high degree of polarization. For example, the third nitride compound comprises Al, Ga, In, AlGa, InGa or InAl.

In examples, the third material contains a transition metal. Thus, in examples, the third nitride compound or the oxide-zinc compound contains a transition metal. The inventors have found that a material, in particular a material having a wurtzite structure, which comprises a transition metal, tends to have a lower coercivity than the corresponding material without a transition metal. In particular, in materials comprising a transition metal the coercivity can be below the breakdown field strength, such that these materials may be ferroelectric. For example, nitride compounds which contain a transition metal may, in contrast to the pure nitride compounds corresponding thereto, be ferroelectric. This can apply in particular to group III nitride compounds. Nitride compounds or oxide compounds comprising zinc, which can furthermore comprise a transition metal, are thus a good compromise between high polarization and the presence of ferroelectricity.

In examples, the transition metal is Sc, Nb, Ti or Y. Nitride compounds comprising these transition metals, in particular group III nitride compounds comprising these transition metals, may be ferroelectric and may have a particularly high degree of polarization and/or a particularly high use temperature. For example, the third material is AlScN or GaScN. The amount of the polarization in AlScN or GaScN can reach values of over 100 μC/cm², and can thus allow particularly efficient shifting of the threshold voltage. Furthermore, the use temperature of AlScN or GaScN can be over 1000° C.

In examples in which the third material is made of the third nitride compound, and the third nitride compound comprises one or more group III elements, a stoichiometric proportion of the transition metal in the third material is between 10% and 50% of a total stoichiometric proportion of the one or more group III elements and the transition metal in the third material. In examples in which the third material is made of the oxide compound, the stoichiometric proportion of the transition metal in the third material is between 10% and 50% of a total stoichiometric proportion of the zinc and the transition metal in the third material. The inventors have found that such a proportion of the transition metal makes it possible to achieve that the second material is both ferroelectric and has a high degree of polarization. The polarization can reduce as the proportion of the transition metal increases, such that a proportion of less than 50% can ensure a particularly high degree of polarization of the second material. It is thus possible for a high charge carrier density to be generated in a charge zone along the main surface of the first layer and/or the second layer. A proportion of over 10% makes it possible to ensure that the second material is ferroelectric.

In examples, the gate electrode and the third layer are part of a gate structure which is arranged so as to be opposite the second layer, in regions. Thus, the charge carrier density in the charge zone can be switched or set in regions, in a region opposite the gate structure.

In examples, the HEMT further comprises a fourth layer, which is arranged between the second layer and the third layer. The fourth layer comprises an electrically conductive material. Thus, the third layer is arranged between the fourth layer and the gate electrode. Building up a voltage between the fourth layer and the gate electrode thus makes it possible for an electrical field to be generated, by means of which the polarization, for example a polarization direction and/or a degree of polarization, of the third material in the third layer, and thus the threshold voltage of the HEMT, can be set. In comparison with implementations in which an electrical field is applied between the gate electrode and the charge zone, in order to set the polarization of the third layer, without any conductive layer between the second and the third layer, the fourth layer offers the advantage that, over the surface thereof, the relationship of the respective electrical fields which are applied over the second layer and the third layer can be set, in order, for example, to prevent electrical breakdowns through the second layer. Furthermore, the fourth layer can create more expedient growth conditions for the third layer, such that the third layer can be deposited at lower temperatures, for example.

In examples, the HEMT further comprises an insulation layer, which is arranged between the second layer and the third layer or between the second layer and the fourth layer. The insulation layer comprises an electrically insulating material, for example Al₂O₃, GaN or AlN. The insulation layer can passivate a further main surface of the second layer that is opposite the main surface of the second layer.

In examples, the gate structure comprises a fourth layer, which is arranged between the second layer and the third layer. The fourth layer comprises an electrically conductive fourth material. Properties and advantages of the fourth layer can correspond to the above-described fourth layer.

In examples, the gate structure further comprises an insulation layer, which is arranged between the second layer and the third layer or between the second layer and the fourth layer. The insulation layer comprises an electrically insulating material. Properties and advantages of the insulation layer can correspond to the above-described insulation layer.

In examples, the fourth material is one of TiN, NbN, Pt, Al, Ti, Ni, Mo.

In examples, the combination of the first material and the second material is one of AlGaN/GaN, AlScN/GaN, AlN/GaN and AlScN/GaScN.

In examples, the HEMT comprises an intermediate layer, which is arranged between the first layer and the second layer. The intermediate layer comprises a material made of a nitride compound. The intermediate layer can change the position of the charge zone in such a way that this is arranged spaced apart from the second layer, for example in the first layer or at the main surface of the first layer (wherein the charge zone can also extend into the intermediate layer). The first layer can be particularly low in defects, since, in examples, it may have been produced epitaxially, such that the charge zone can have a particularly high conductivity when it is located at least largely in the first layer.

In examples, the material of the intermediate layer is one of AlN and GaN.

In examples, a polarization state of the third material can be set by applying a voltage to the gate electrode. In these examples, a threshold voltage of the HEMT, at which a conduction channel through the charge zone changes between an enabled state and a disabled state, is dependent on the polarization state of the third material. The threshold voltage can for example refer to a voltage that is required between the gate electrode and the charge zone and is intended for changing between the enabled and the disabled state. The change between the enabled state and the disabled state can be characterized, for example, by a conductivity or a resistance of the charge zone. Accordingly, the threshold voltage of the HEMT can be set by applying a voltage to the gate electrode.

In examples, the third material has a first polarization state. The threshold voltage of the HEMT is positive when the third material is in the first polarization state. A polarization state can be characterized by a polarization direction and a degree of polarization. In examples in which the charge zone is configured to form a 2DEG, the polarization direction of the third material in the first polarization state can face away from the charge zone, at least in part. A positive threshold voltage means that the HEMT is disabled when no voltage is applied to the gate electrode, i.e. the HEMT is in a normally-off state.

In examples, the third material furthermore has a second polarization state and the threshold voltage is negative, when the third material is in the second polarization state. In examples, the degree of polarization of the second polarization state can be less than the degree of polarization of the first polarization state. In further examples, the polarization direction of the second polarization state can face towards the charge zone, at least in part. A negative threshold voltage means that the HEMT is enabled when no voltage is applied to the gate electrode, i.e. the HEMT is in a normally-on state. Setting the polarization state of the third material between the first polarization state and the second polarization state thus makes it possible for the HEMT to be changed between a normally-off and a normally-on state.

In examples, the gate electrode is arranged in a gate electrode region, such that the polarization state of the third material, in a first region of the third layer opposite the gate electrode region, can be set by applying a voltage to the gate electrode. The third layer further comprises a second region that is different from the first region. The third material of the second region of the third layer is in a polarization state for which a charge zone region of the charge zone that is opposite the second region is in a conductive state.

In examples, the HEMT comprises a source region and a drain region. The charge zone is arranged electrically in series between the source region and the drain region. Setting the charge carrier density in the charge zone, for example by applying a voltage to the gate electrode or by setting the polarization state of the third material, thus makes it possible for the conductivity between the source region and the drain region to be set.

Further examples of the present invention provide a transistor assembly comprising an HEMT according to the present invention, which furthermore comprises a control signal generator. The control signal generator is configured to apply a voltage to the gate electrode, in order to set a polarization direction in a region of the third layer that is opposite the gate electrode. Setting the polarization direction allows for efficient setting of the threshold voltage of the HEMT. For example, the third layer in the region opposite the gate electrode can be polarized completely or virtually completely, in one direction, by applying a voltage of a magnitude greater than a critical value.

In examples, the control signal generator is configured to set a degree of polarization in the region of the third layer that is opposite the gate electrode, by means of applying the voltage to the gate electrode, in order to set a threshold voltage of the HEMT. For example, in order to set the degree of polarization a voltage can be selected which results in a non-uniform polarization of the third material in the region opposite the gate electrode. Setting the degree of polarization makes it possible for the threshold voltage to be precisely set.

In examples, the control signal generator is configured to apply a first voltage between the gate electrode and the charge zone, in order to set the threshold voltage to a positive value, and to apply a second voltage between the gate electrode and the charge zone, in order to set the threshold voltage to a negative value.

Further examples of the present invention provide a method for controlling the HEMT according to the invention. The method includes a step of applying a voltage to the gate electrode, in order to set a polarization direction and/or a degree of polarization of the third material, in order to set a threshold voltage of the HEMT, at which a conduction channel through the charge zone changes between an enabled state and a disabled state. Thus, the threshold voltage can be set according to the application of the HEMT.

Further examples of the present invention provide a method for controlling the HEMT according to the invention. The method includes a step of applying a first voltage to the gate electrode, in order to set a polarization direction and/or a degree of polarization of the third material, such that a threshold voltage of the HEMT, at which a conduction channel through the charge zone changes between an enabled state and a disabled state, is positive. Thus, the HEMT can be operated in a normally-off state.

Further examples of the present invention provide a method for producing an HEMT. The method comprises providing a layer structure comprising a first layer, a second layer and a third layer. The third layer comprises a ferroelectric material. The provision of the layer structure takes place in such a way that the second layer is arranged between the first layer and the third layer. Furthermore, the provision of the layer structure takes place in such a way that a main surface of the second layer is arranged opposite a main surface of the first layer. The provision of the layer structure takes place in such a way that a charge zone forms along the main surface of the first layer. The method further comprises applying a source contact and a drain contact, in such a way that the charge zone is arranged electrically in series between the source contact and the drain contact. The method further comprises temperature treatment, or annealing, of the layer structure together with the source contact and the drain contact.

By means of the temperature treatment, an ohmic contact between the source contact and the charge zone, or between the drain contact and the charge zone, can be achieved or improved. The inventors have found that an HEMT can be produced in a particularly uncomplicated manner when the temperature treatment takes place at a point of the production process at which the layer structure comprises the third layer.

According to one embodiment, the provision of the layer structure includes an epitaxial application of a first layer and a second layer in such a way that a main surface of the second layer is arranged opposite a main surface of the first layer, and such that a charge zone forms along the main surface of the first layer, and such that the first layer comprises a first material having a wurtzite crystal structure and the second layer comprises a second material having a wurtzite crystal structure. Furthermore, the provision of the layer structure includes an epitaxial application of a ferroelectric third layer in such a way that the second layer is arranged between the first layer and the third layer, and such that the third layer comprises a ferroelectric third material having a wurtzite crystal structure.

Further examples of the present invention provide a method for producing an HEMT. The method includes an epitaxial application of a first layer and a second layer in such a way that a main surface of the second layer is arranged opposite a main surface of the first layer, and such that a charge zone forms along the main surface of the first layer. Furthermore, the epitaxial application of the first layer and the second layer takes place in such a way that the first layer comprises a first material having a wurtzite crystal structure and the second layer comprises a second material having a wurtzite crystal structure. The method further includes an epitaxial application of a ferroelectric third layer in such a way that the second layer is arranged between the first layer and the third layer, and such that the third layer comprises a ferroelectric third material having a wurtzite crystal structure.

The inventors have found that an HEMT can be produced in a particularly uncomplicated and defect-free manner in that the first layer, the second layer and the third layer are produced epitaxially. For this purpose, it is particularly advantageous if the first layer, the second layer and also the ferroelectric third layer have a wurtzite crystal structure.

### BRIEF DESCRIPTION OF THE DRAWINGS

Examples of the invention are described in the following, with reference to the accompanying drawings, in which:

FIG. 1 is a schematic view of an HEMT according to an embodiment;

FIG. 2 is a schematic view of a further example of the HEMT comprising a gate electrode;

FIG. 3 is a schematic view of a further example of the HEMT comprising a gate structure;

FIG. 4 is a schematic view of a further example of the HEMT comprising gate electrodes arranged in regions;

FIG. 5 is a schematic view of a further example of the HEMT comprising a gate structure;

FIG. 6 is a flow diagram of a method for switching the HEMT according to one embodiment;

FIG. 7 is a flow diagram of a method for switching the HEMT according to a further embodiment;

FIG. 8 is a flow diagram of a method for producing the HEMT according to one embodiment; and

FIG. 9 is a flow diagram of a method for producing the HEMT according to a further embodiment.

### DETAILED DESCRIPTION OF THE INVENTION

In the following, examples of the present invention are described in detail and using the accompanying descriptions. In the following description, many details are described, in order to provide a more thorough explanation of examples of the disclosure. However, it is obvious to a person skilled in the art that other examples without these specific details can be implemented. Features of the different described examples can be combined with one another, unless features of a corresponding combination are mutually exclusive, or such a combination is explicitly excluded.

It is noted that identical or similar elements, or elements having the same function, may be provided with identical or similar reference signs or the same designation, wherein a repeated description of elements that are provided with identical or similar reference signs or the same designation are typically omitted. Descriptions of elements that have the same or similar reference signs or the same designation are interchangeable.

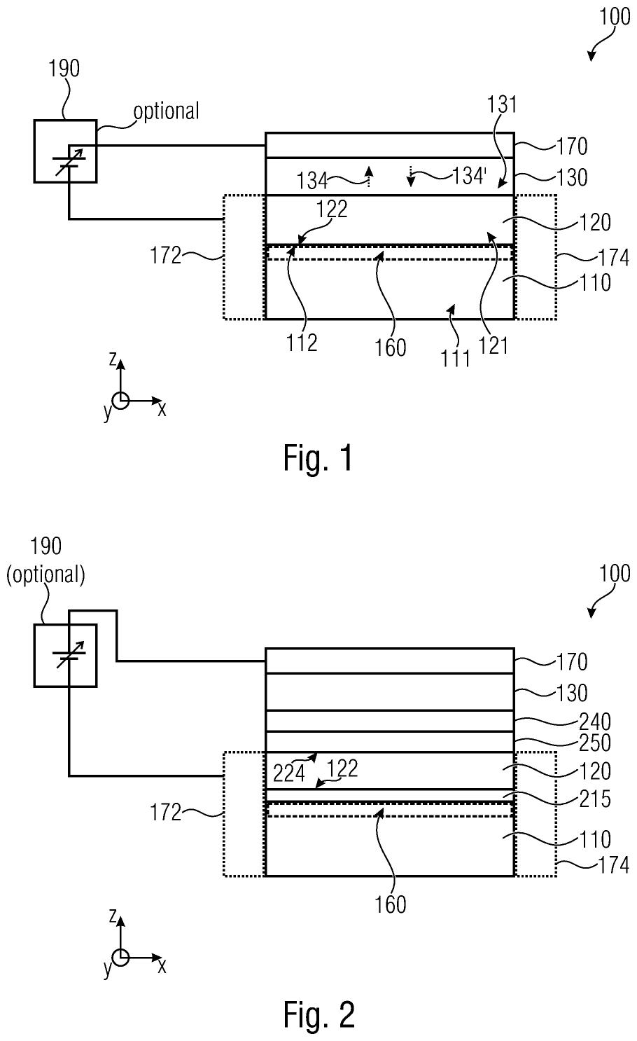

FIG. 1 is a schematic view of an HEMT 100 according to an example of the invention. The HEMT 100 comprises a first layer 110 and a second layer 120. The first layer 110 comprises a first material 111 made of a first nitride compound. The first nitride compound comprises a group III element. The second layer 120 comprises a second material 121 made of a second nitride compound. The second nitride compound comprises a group III element. A main surface 122 of the second layer 120 is arranged opposite a main surface 112 of the first layer 110, such that a charge zone 160 forms along the main surface 112 of the first layer. The HEMT further comprises a gate electrode 170. The gate electrode 170 is arranged opposite the second layer 120, at least in regions, such that the second layer 120 is arranged between the first layer 110 and the gate electrode 170. Furthermore, the HEMT comprises a third layer 130. The third layer 130 is arranged between the gate electrode 170 and the second layer 120. The third layer 130 comprises a ferroelectric third material 131. The third material 131 is made of a third nitride compound. Alternatively, the third material 131 is made of an oxide compound which contains zinc, for example of zinc oxide or of a zinc oxide compound.

FIG. 1 shows a cartesian coordinate system that is selected by way of example. In examples, the first layer 110, the second layer 120 and the third layer 130 can be arranged along the z-direction and each extend in the x-y plane.

In examples, the first layer 110, the second layer 120, the third layer 130 and the gate electrode 170 are part of a layer structure. Each of the layers of the layer structure can comprise a main surface and a further main surface opposite the main surface. The main surfaces of the layers can be arranged in parallel with one another along a main direction of the layer structure. In examples, the first layer 110, the second layer 120, the third layer 130 and the gate electrode 170 can be arranged in parallel with the x-y plane.

The layer structure can be characterized, for example, in that two of its layers are separated from one another at least by a boundary surface. The boundary surface between two layers of the layer structure, arranged adjacently to one another, can thus be formed of the mutually facing main surfaces of the two layers. In this case, a boundary surface can constitute a boundary surface between two different materials, which may differ from one another for example by their composition and/or their structure.

An opposing arrangement of a main surface of a first layer and a main surface of a second layer can mean that these main surfaces are arranged facing one another. As shown in FIG. 1, the main surface 112 of the first layer 110 faces the second layer 120, and correspondingly the main surface 122 of the second layer 120 faces the first layer.

For example, the first material 111 and the second material 121 are semi-conductive materials, the bandgaps of which are matched to one another such that an extremum in a potential curve in the z-direction, which can provide the charge zone 160, forms along the main surface 112. The extremum can be a minimum, such that a 2DEG can form along the main surface 112.

In examples, the combination of the first material 111 and the second material 121 is one of AlGaN/GaN, AlScN/GaN, AlN/GaN and AlScN/GaScN.

In examples, both the first material and the second material have a wurtzite crystal structure.

Since the third material 131 is ferroelectric, a polarization state of the third material 131 can be set, in that the third material 131 is subjected to an electrical field. The polarization state of a ferroelectric material can also be maintained after the application of the electrical field, for example in that an electrical field of sufficient magnitude having an opposing direction is applied. For example, a voltage can be applied between the gate electrode 170 and the charge zone 160, e.g. via a source region or drain region, in order to generate said electrical field. The third material 131 in the third layer 130 or within a considered region in the third layer 130 can be polarized completely in one direction or polarized in part. For example, individual local domains can be polarized in one direction, and further domains can be non-polarized or polarized in a different direction. The polarization state of the third material 131 or a considered region of the third material 131 can relate to a polarization averaged over the third material 131 or the considered region of the third material 131. In FIG. 1, a first polarization state 134 is shown by way of example, the polarization direction of which faces away from the second layer 120 at least in part, and a second polarization state 134′ is shown, the polarization direction of which faces towards the second layer 120, at least in part.

The polarization of the third material 131 can act on the polarization of the charge zone 160, similarly to an electrical field applied by means of a gate electrode. Depending on the polarization state of the third material 131, the charge zone 160 can be depleted accordingly, i.e. blocking, or can be conductive. Furthermore, the potential of the charge zone 160 can be varied by means of a field effect, by applying a voltage between the gate electrode 170 and the charge zone 160, in order to vary the charge carrier density in a region of the charge zone 160 opposite the gate electrode 170, and thus enable or disable the conductivity of the charge zone 160. A voltage required between the gate electrode 170 and the charge zone 160, at which a conduction channel through the charge zone 160 changes between an enabled state and a disabled state, can also be referred to as the threshold voltage of the HEMT. In examples, the threshold voltage of the HEMT can be set gradually by setting the degree of polarization of the third layer 130.

In examples in which the majority load carriers of the charge zone 160 are electrons, the charge zone can thus comprise a 2DEG or be formed by a 2DEG, and a polarization direction of the third material in the z-direction can bring about a positive shift of the threshold voltage of the HEMT, for example the first polarization state 134. A polarization direction of the third material in the z-direction can bring about a negative shift of the threshold voltage of the HEMT, for example the second polarization state 134′. In this case, the magnitude of the shift of the threshold voltage can depend on the degree of polarization. That is to say that the transition between a positive and a negative threshold voltage can, in examples, take place by means of a change in the degree of polarization of the third layer, wherein the polarization direction does not necessarily have to change.

The strength of the electrical field which may be required for changing or switching the polarization of the third material 131 can, in examples, be between 0.1 MV/cm and 8 MV/cm. A layer thickness of the third layer 130 can be in a range of 5-1000 nm, for example. For example, the strength of the electrical field for switching the polarization can be influenced by the selection of the layer thickness of the third layer 130.

In examples in which the majority charge carriers in the charge zone are electrons, the HEMT can be configured such that the threshold voltage (taking into account the sign) is smaller, for example at least by a factor of 1.2, a factor of 1.5, a factor of two, or a factor of five, than a voltage at which the polarization of the third material 131 changes substantially, for example by more than 50% or by more than 30% or by more than 10%. It is thus possible to ensure that an electrical field can be established between the charge zone and the gate electrode, which field is sufficient for setting the polarization of the third material to the second polarization state.

In examples, the polarization state of the third material 131 can be set by applying a voltage to the gate electrode 170. A threshold voltage of the HEMT, at which a conduction channel through the charge zone 160 changes between an enabled state and a disabled state, is dependent on the polarization state of the third material 131.

In examples in which the charge zone 160 forms a 2DEG, in a conductive state, a polarization direction of the third material 131 which faces at least in part in the direction of the second layer 120, i.e. counter to the z-direction, can lead to a shift of the threshold voltage by a positive value, while a polarization direction of the third material 142 which faces at least in part away from the second layer 120, i.e. in the z-direction, can lead to a shift of the threshold voltage by a negative value.

In examples, the third material 131 has a first polarization state. If the third material 131 is in the first polarization state, the threshold voltage of the HEMT is positive. For example, the first polarization state may be a polarization state, the polarization direction of which is oriented at least in part along the z-direction, e.g. the polarization state 134. In examples in which the charge zone 160 forms a 2DEG, in a conductive state, a positive threshold voltage can mean that a conduction channel through the charge zone 160 is disabled when no voltage is applied to the gate electrode.

In examples, the third material 131 furthermore has a second polarization state. If the third material 131 is in the second polarization state, the threshold voltage of the HEMT is negative. For example, the second polarization state may be a polarization state, the polarization direction of which is oriented at least in part counter to the z-direction, for example counter to the first polarization state, e.g. the polarization state 134′. Alternatively, the second polarization state can have the same polarization direction as the first polarization state, but a lower degree of polarization than the first polarization state. In examples in which the charge zone 160 forms a 2DEG, in a conductive state, a negative threshold voltage can mean that a conduction channel through the charge zone 160 is enabled when no voltage is applied to the gate electrode.

In examples, the HEMT 100 furthermore contains a source region 172 and a drain region 174, which are arranged in such a way that the charge zone 160 is arranged electrically in series between the source region 172 and the drain region 174. The arrangement of the source region 172 and the drain region 174 is to be understood as being by way of example. For example, the source region 172 and the drain region 174 can be arranged adjoining the first layer 110 and/or adjoining the second layer 120. In a conductive state, the charge zone 160 can provide a conduction channel between the source region 172 and the drain region 174. Thus, the conduction channel between the source region 172 and the drain region 174 can be enabled or disabled by applying a voltage to the gate electrode 170.

In examples, the third material 131 has a wurtzite crystal structure.

Thus, in examples, the first material 111, the second material 121 and the third material 131 can have a wurtzite crystal structure.

In examples, the third material 131 comprises a nitride compound, which comprises one or more group III elements. For example, the nitride compound of the third material 131 comprises one or more of Al, Ga, and In.

Both for the case where the third material 131 is a nitride compound, and for the case where the third material 131 is an oxide compound comprising zinc, the third material 131 can comprise a transition metal. The transition metal can optionally be one of Sc, Nb, Ti or Y. In examples, the third material is AlScN or GaScN.

In examples, the third material 131 is a nitride compound, which comprises one or more group III elements and a transition metal. In these examples, a stoichiometric proportion of the transition metal in the nitride compound of the third material 131 can be between 10% and 50% of a total stoichiometric proportion of the one or more group III elements and the transition metal in the nitride compound. For example, the third material 131 has the chemical formula A₍₁₋ₓ₎TₓN, where A represents a group III element or a plurality of different group III elements, T represents a transition metal, N is nitrogen, and x is between 0.1 and 0.5.

In examples, the third material 131 is an oxide compound, which comprises one or more group III elements and a transition metal. In these examples, a stoichiometric proportion of the transition metal in the oxide compound of the third material 131 can be between 10% and 50% of a total stoichiometric proportion of the zinc and the transition metal in the nitride compound. For example, the third material 131 has the chemical formula Zn₍₁₋ₓ₎TₓN, where T represents a transition metal, and x is between 0.1 and 0.5.

In examples, the third material 131 has a lower coercivity than the second material 121. The second material 121 can thus also be ferroelectric. For example, the third material 131 has a lower coercivity than the second material 121, in order to switch or to change a polarization portion of the respective material in a direction perpendicular to the main surface of the second layer.

As a result, the polarization direction of the third material can be changed or switched by means of an electrical field between the gate electrode 170 and the charge zone 160, which field has a field strength that is greater than the coercivity of the third material 131 and less than the coercivity of the second material 121, without substantially changing the polarization direction of the second material.

For example, the mentioned relationship between the coercivities can be achieved in that, in particular in examples in which the first, second and third material, in that the third material have a wurtzite crystal structure, in that the third material, or the third layer, has a high proportion of a transition metal than the second material, or the second layer. The proportion of the transition metal is for example the described proportion of the transition metal in the nitride compound.

Alternatively or additionally, the mentioned relationship between the coercivities can be achieved in that the third material 131 has a tensile stress. For example, the third layer has a lattice constant, in the direction perpendicular to the main surface of the second layer, which is greater than a reference lattice constant. The reference lattice constant can for example be an equilibrium lattice constant of the third material. The tensile stress can for example be generated by a production process, for example in the case of deposition, of the third layer, in the third material.

FIG. 2 is a schematic view of a further example of the HEMT 100. The HEMT 100 can comprise a fourth layer 240 which is arranged between the second layer 120 and the third layer 130. The fourth layer 240 comprises an electrically conductive material. For example, the electrically conductive material of the fourth layer 240 is one of TiN, NbN, Pt, Al, Ti, Mo, or Ni. The fourth layer 240 can be arranged such that the third layer 130 is arranged between the fourth layer 240 and the gate electrode 170. The fourth layer 240 can serve as a floating gate. That is to say that the fourth layer 240 can be potential-free, i.e. not switched to a particular potential. A relationship between the fourth layer 240 and the gate electrode 170 can determine the electrical field strength through the third layer. Expediently, the fourth layer 240 has a larger surface area than the gate electrode 170. It is thus possible to achieve a sufficiently high electrical field strength through the third layer 130, in order to change the polarization of the third material, while the electrical field strength through the second layer is sufficiently small in order to prevent a breakdown or ferroelectric switching. In this case, the surface area of the fourth layer or the gate electrode can refer to an extension in a plane in parallel with the layers, i.e. for example in parallel with the main surface of the first layer 110 or the second layer 120. In other words, a surface measurement of a main surface of the fourth layer 240 arranged opposite the gate electrode can be larger than a surface measurement of a main surface of the gate electrode arranged opposite the fourth layer. In this case, the main surface of the fourth layer can be arranged opposite a main surface of the second layer, for example arranged in parallel therewith.

Accordingly, in examples, an electrical capacitance between the gate electrode 170 and the fourth layer 240 is smaller than an electrical capacitance between the fourth layer 240 and the charge zone 160, for example when the charge zone is in a conductive state.

In examples, the HEMT 100 further comprises an insulation layer 250. The implementation of the insulation layer 52 is independent of the implementation of the fourth layer 240. The insulation layer 250 can, as shown in FIG. 2, be arranged between the second layer 120 and the fourth layer 240. In other examples, the insulation layer 250 can be implemented without the fourth layer 240. In these examples, the insulation layer 250 is arranged between the second layer 120 and the third layer 130. The insulation layer 250 can passivate a further main surface 224 that is opposite the main surface 122 of the second layer 120. The insulation layer 250 comprises an electrically insulating material, for example one made of Al₂O₃, GaN or AlN.

In examples, the HEMT 100 further comprises an intermediate layer 215. The intermediate layer 215 is arranged between the first layer 110 and the second layer 120. The intermediate layer 215 comprises a material made of a nitride compound. The intermediate layer 215 can for example be less than 10 nm thick. The intermediate layer 215 can cause the charge zone 160 to be located in the first layer 110. The first layer 110 can be particularly low in defects, such that the conductivity of a conduction channel through the charge zone 160 can be particularly high when the charge zone 160 is located in the first layer 110. In examples, the material of the intermediate layer 215 can be one of AlN and GaN. These materials are suitable in particular when the combination of the first material 111 and the second material 121 is one of AlGaN/GaN, AlScN/GaN and AlScN/GaScN. The intermediate layer 215 can be arranged adjoining the main surface 112 of the first layer 110, and adjoining the main surface 122 of the second layer 120. In the case of implementations without the intermediate layer 215, the main surface 112 of the first layer 110 can be arranged adjoining the main surface 122 of the second layer 120. The intermediate layer 215 can be implemented independently of the fourth layer 240 and the insulation layer 250.

The fourth layer 240, the insulation layer 250 and the intermediate layer 215 can be implemented independently of one another, in the example shown in FIG. 1.

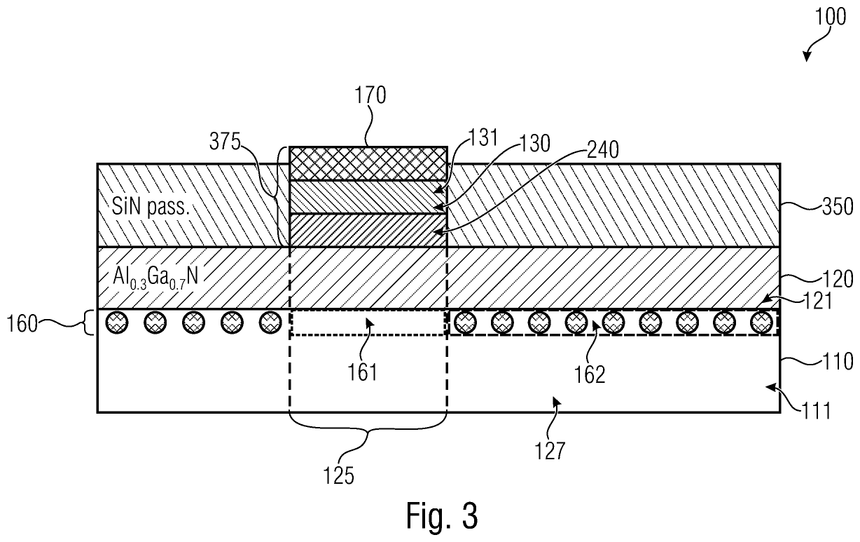

FIG. 3 is a schematic view of a further example of the HEMT 100. According to this example, the gate electrode 170 and the third layer 130 are part of a gate structure 375. The gate structure 375 is arranged opposite the second layer 120, in regions.

In the example shown in FIG. 3, the gate structure 375 is arranged opposite a first region 125 of the first layer 110 and the second layer 120. The first layer 110 and the second layer 120 can furthermore comprise a second region 127 which is different from the first region 125. The polarization of the third layer 130 can influence the charge carrier density in a region 161 of the charge zone 160 opposite the gate structure 375. A second region 162 of the charge zone 160 located in the second region 127 of the first layer 110 and/or the second layer 120 can remain largely uninfluenced by the polarization of the third layer 130 (aside from edge effects, for example). In the example shown in FIG. 3, the gate structure 375 further comprises the fourth layer 240. The gate structure 375 can, however, also be implemented without the fourth layer 240 and/or additionally with the insulation layer 250, as described in FIG. 2. Optionally, in the example shown in FIG. 3, the intermediate layer 215 can also be implemented.

In an example of the implementation of the HEMT 100 shown in FIG. 3, the first material 111 is intrinsic GaN, the second material 121 is Al_{0.3}Ga_{0.7}N, the third material 131 is AlScN. Optionally, in this example, the material of the fourth layer 240 can be TiN.

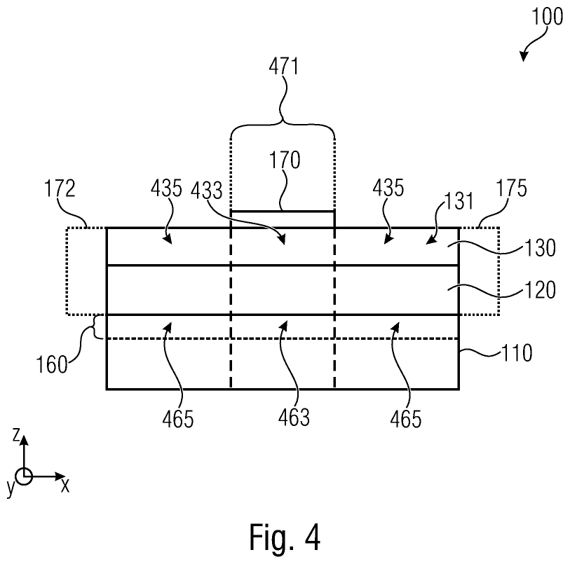

FIG. 4 is a schematic view of a further example of the HEMT 100. According to the example from FIG. 4, the gate electrode 170 is arranged in a gate electrode region 471, such that the polarization state of the third material 131 in a first region 433 of the third layer 130 opposite the gate electrode region 471 can be set by applying a voltage to the gate electrode 170. The third layer 130 further comprises a second region 435 that is different from the first region 433. The third material of the second region 435 of the third layer 130 is in a polarization state for which a charge zone region 465 of the charge zone 160 that is opposite the second region 435 is in a conductive state.

Setting the polarization state of the third material in the first region 433 of the third layer 130 makes it possible, for example, for a threshold voltage for the conductivity of a charge zone region 463 of the charge zone 160 opposite the gate electrode 170 to be set. Furthermore, the gate electrode 170 can be used to enable or disable a conduction channel through the further charge zone region 463.

The gate electrode region 471 can extend completely over a channel region arranged between the source region 172 and the drain region 174, in a direction (e.g. the y-direction) transverse to a direction (e.g. the x-direction) between the source region 172 and the drain region 174, such that the source region 172 and the drain region 174 are electrically insulated from one another if the further charge zone region 463 is in an electrically insulating state. The surface of the gate electrode 471 can for example be precisely so large that a conduction channel between the source region 172 and the drain region 174 can be disabled, but under this condition can be as small as possible in order to prevent leakage currents between the charge zone 160 and the gate electrode 170, and keep the capacitance of the gate electrode small. At the same time, a distance between the source region 172 and the drain region 174 can be so large that voltage breakdowns can be prevented, for example even in the case of voltages of over 100 V between the source region 172 and the drain region 174, or between the source region 172 and the gate electrode 170, or between the drain region 174 and the gate electrode 170. In examples, a dimension of the gate electrode 170 in a direction from the source region 172 to the drain region 174 is between 10% and 80%, or between 40% and 60% of the distance between the source region 172 and the drain region 174.

In the example shown in FIG. 4, the fourth layer 240, the insulation layer 250 and the intermediate layer 215 can be implemented optionally and independently of one another. In examples, the fourth layer 240 can be arranged in a region opposite the gate electrode 170.

The implementation of the HEMT 100 shown in FIG. 3 and FIG. 4 can further comprise the source region 172 and the drain region 174 as explained with reference to FIG. 1.

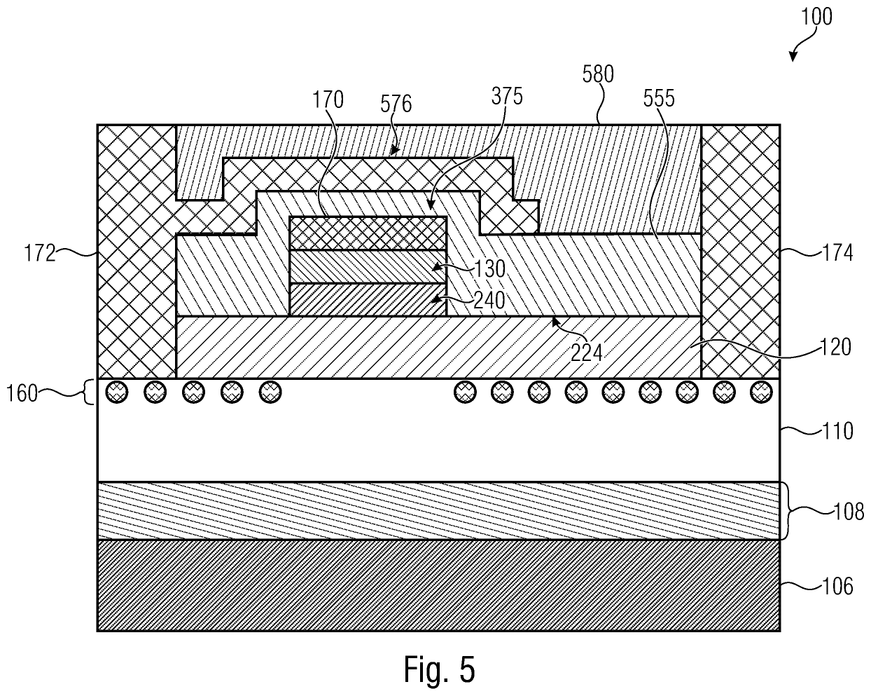

FIG. 5 is a schematic view of a further example of the HEMT 100. According to this example, the HEMT 100 comprises a substrate 106 which is arranged opposite the first layer 110, such that the first layer 110 is arranged between the substrate 106 and the second layer 120. The substrate 106 can for example comprise Si, SiC or GaN. Furthermore, the HEMT 100 comprises a multilayer lattice buffer 108 which is arranged between the substrate 106 and the first layer 110. The lattice buffer 108 contains a plurality of layers of different materials, which contain for example a plurality or all of GaN, AlGaN, AlN. The lattice buffer 108 can serve to create a transition between the lattice constants of the substrate 106 and the lattice constants of the first layer 110, as a result of which the first layer 110 can be produced on the substrate 106 such that it is low in defects. The substrate 106 and the lattice buffer 108 can also be implemented in the examples shown in FIG. 1 to FIG. 4.

In the example shown in FIG. 5, the source region 172 and the drain region 174 are arranged adjoining the main surface 112 of the first layer 110, as a result of which an electrical contact of the source region 172 and of the drain region 174 to the charge zone 160 is ensured.

Furthermore, in the example shown in FIG. 5, the gate structure 375 is arranged adjoining a region of the further main surface 224 of the second layer 120. The HEMT 100 can comprise a passivation layer 555, which can comprise an electrically insulating material, e.g. SiN. For example, the passivation layer 555 can be arranged adjoining a region of the further main surface 224 of the second layer 120 that is not adjacent to the gate structure 375. Furthermore, the passivation layer 555 can be arranged adjoining the gate structure 375.

The HEMT 100 can further comprise a shielding layer 576, which can comprise an electrically conductive material. The shielding layer 576 can for example be electrically conductively connected to the source region 172 or the drain region 174. The shielding layer 576 is arranged opposite the gate electrode 170, such that the gate electrode is arranged between the shielding layer 576 and the second layer 120. Furthermore, an electrically insulating layer, for example the passivation layer 555, is arranged between the shielding layer 576 and the gate electrode 170. If a voltage is applied between the gate electrode 170 and the source region 172, in order to generate a field effect between the gate electrode 170 and the charge zone 160 that is electrically connected to the region 120, the arrangement of the shielding layer 576 can shield the gate electrode relative to the drain region 174. Furthermore, the arrangement of the shielding layer 576 can ensure a distribution of the electrical fields of the gate electrode, such that strong local fields can be prevented and thus the reliability of the components can be increased.

The HEMT 100 can further comprise a fifth layer 580, which can comprise an electrically insulating material 580, e.g. an oxide compound. The fifth layer 580 can be arranged adjoining the passivation layer 555 and/or the shielding layer 576, such that the passivation layer 555 and/or the shielding layer is arranged between the fifth layer 580 and the second layer 120. For example, the fifth layer 580 can completely cover a region between the source region and the drain region. The fifth layer can serve for passivation, in particular passivation of the shielding layer 576.

In an example of the implementation of the HEMT 100 shown in FIG. 5, the substrate 106 is made of Si, SiC or GaN. The lattice buffer 108 can comprise at least layers of GaN, AlGaN, AlN. The first material 111 can be intrinsic GaN, the second material can be Al_{0.3}Ga_{0.7}N, the third material 131 is AlScN. Optionally, the fourth layer 240 can be made of TiN. The passivation layer 555 can be made of SiN for example.

As shown in FIG. 1 and FIG. 2, the HEMT 100 can optionally be part of a transistor assembly, which comprises the HEMT 100 and a control signal generator 190. This also relates to the examples in FIG. 3 to FIG. 5. The control signal generator 190 is configured to apply a voltage to the gate electrode 170, in order to set a polarization direction in a region of the third layer 130 that is opposite the gate electrode 170.

For example, the control signal generator 190 is configured to set a degree of polarization in the region of the third layer 130 that is opposite the gate electrode 170, by means of applying the voltage to the gate electrode 170, in order to set a threshold voltage of the HEMT 100.

For example, the control signal generator 190 can be configured to apply a voltage to the gate electrode 170, at which the third material is polarized completely or in part, in the region opposite the gate electrode 170, in a manner corresponding to the polarity of the applied voltage, wherein the magnitude of the applied voltage can determine the degree of polarization, i.e. at which part the third material is polarized, in the region opposite the gate electrode 170, in a manner corresponding to the polarity of the applied voltage.

The control signal generator 190 can be configured to apply a first voltage between the gate electrode 170 and the charge zone 160, in order to set the threshold voltage to a positive value. Furthermore, the control signal generator can be configured to apply a second voltage between the gate electrode 170 and the charge zone 160, in order to set the threshold voltage to a negative value. The control signal generator 190 can apply the first voltage for example between the gate electrode 170 and the source region 172 or the drain region 174.

In examples of the HEMT 100 according to FIG. 1 to 5, the polarization state of the third material 131 can be set such that the HEMT has a high threshold voltage. As a result, the HEMT 100 can be suitable for example for logic components, which are intended to keep stable an enabled or disabled state. In examples, the threshold voltage can be set by means of setting the polarization state of the third material 131 to a positive or a negative value, such that the HEMT 100 can be well suited for programmable logic components. Furthermore, the HEMT 100 can allow for implementations for current converters which change their functionality (e.g. buck <-> boost) depending on the relationship of the input and output voltage. In other examples, the HEMT 100 can be used for current converters which can connect or disconnect components, depending on the output power.

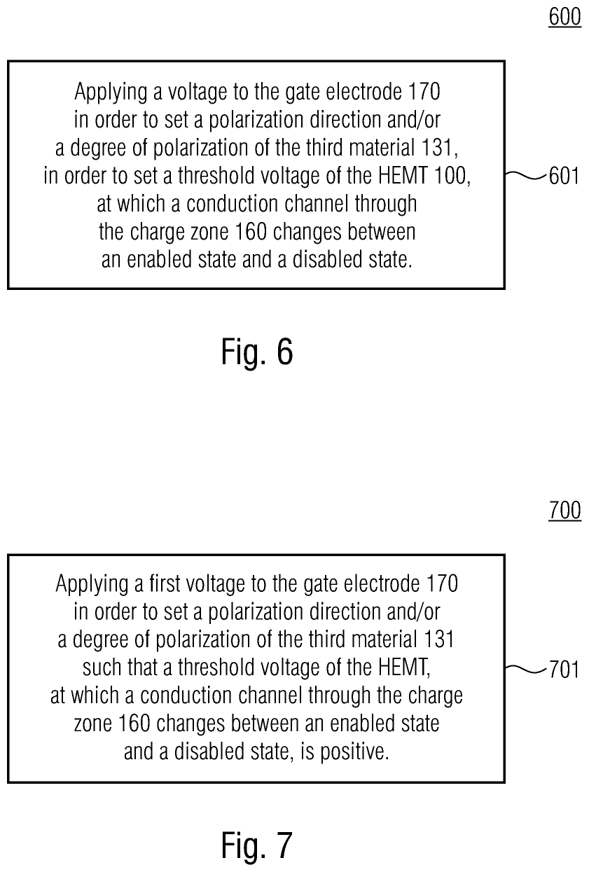

FIG. 6 is a flow diagram of a method 600 for controlling the HEMT 100 according to one embodiment. The method includes a step 601 of applying a voltage to the gate electrode, in order to set a polarization direction and/or a degree of polarization of the third material 131, in order to set a threshold voltage of the HEMT 100, at which a conduction channel through the charge zone 160 changes between an enabled state and a disabled state.

FIG. 7 is a flow diagram of a method 700 for controlling the HEMT 100 according to one embodiment. The method includes a step 701 of applying a voltage to the gate electrode 170, in order to set a polarization direction and/or a degree of polarization of the third material 131, such that a threshold voltage of the HEMT 100, at which a conduction channel through the charge zone 160 changes between an enabled state and a disabled state, is positive.

For example, the application 601, 701 of the voltage to the gate electrode 170 can take place, in the methods 600 or 700, by applying a voltage between the gate electrode 170 and the charge zone 160, or by applying a voltage between the gate electrode 170 and the fourth layer 240.

In examples, the methods 600, 700 from FIG. 6 and FIG. 7 can furthermore include applying a voltage between the gate electrode 170 and the charge zone 160, in order to enable or disable a conduction channel through the charge zone 160.

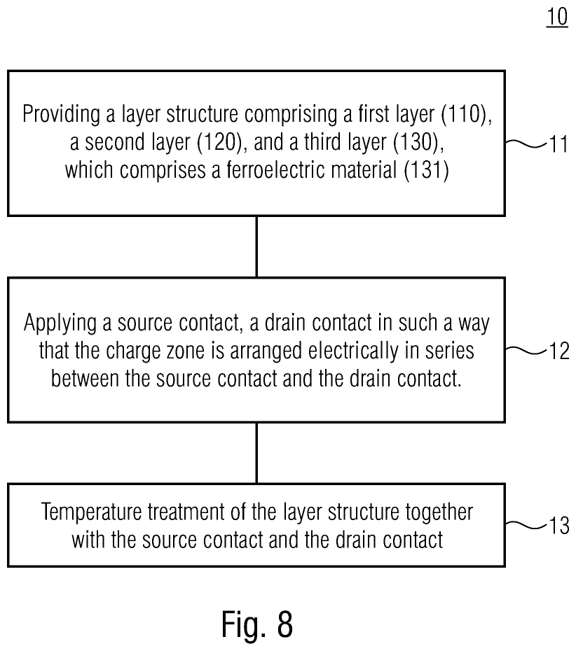

FIG. 8 is a flow diagram of a method 10 for producing the HEMT according to one embodiment. The method 10 contains a step 11 which comprises providing a layer structure comprising a first layer 110, a second layer 120, and a third layer 130. The third layer 130 comprises a ferroelectric material 131. The provision of the layer structure takes place in such a way that the second layer 120 is arranged between the first layer 110 and the third layer 130, and such that a main surface 122 of the second layer 120 is arranged opposite a main surface 112 of the first layer 110. Furthermore, the provision of the layer structure takes place in such a way that a charge zone 160 forms along the main surface 112 of the first layer 110. This can be achieved for example by a selection of the materials of the first layer 110 and the second layer 120 as described in view of FIG. 1 to FIG. 5. The method 10 further includes a step 12 which comprises application of a source contact 172 and a drain contact 174. The step 12 can take place for example by depositing a metal. The application of the source contact 172 and of the drain contact 174 takes place in such a way that the charge zone 160 is arranged electrically in series between the source contact and the drain contact. Furthermore, the method 10 includes a step 13 which comprises a temperature treatment, for example annealing, of the layer structure together with the source contact and the drain contact.

By means of the temperature treatment, an ohmic contact between the source contact 172 and the charge zone 160, and between the drain contact 374 and the charge zone 160 can be achieved or improved. For example, the temperature treatment can include exposing the layer structure, together with the source contact and the drain contact, to a temperature of over 700° C.

The first layer 110, the second layer 120, the third layer 130 can be produced by means of the method 10 as described with respect to FIG. 1 to 5. In particular, the first layer 110, the second layer 120, the third layer 130 can comprise the materials as described with respect to FIG. 1 to 5. In particular, the third layer 130 can comprise a ferroelectric third material 131. Since the ferroelectric third material 131 described with respect to FIG. 1 to 5 is particularly temperature-stable, the step 13 can be carried out with the layer structure including the third layer 130, without damaging the third layer 130. This applies in particular if the third material 130 is a group III nitride compound which comprises a transition metal such as AlScN.

Step 11 of providing the layer structure can optionally comprise a step of providing a layer structure comprising the first layer 110 and the second layer 120, and furthermore a further step of applying the third layer 130. Furthermore, step 11 can comprise structuring of the third layer 130. For example, regions of the third layer can be removed, such that the application of the source contact 172 and of the drain contact 174 in step 12 can take place in such a way that the source contact 172 and the drain contact 174 are arranged adjoining the second layer. In other examples, step 11 can also comprise partial removal of the second layer, such that the application of the source contact 172 and of the drain contact 174 in step 12 can take place in such a way that the source contact 172 and the drain contact 174 are arranged adjoining the first layer 110.

In examples, step 12 further comprises application of a gate electrode 170.

Step 12 can take place in such a way that the source contact 172 and the drain contact 174, and optionally the gate electrode 170, fulfil the properties and the arrangement as described with respect to FIG. 1 to 5.

In examples, step 11 comprises applying or depositing the first layer 110 onto a substrate or onto a lattice adjustment layer on a substrate. Furthermore, step 11 can include applying or depositing the second layer 120 onto the first layer 110. Alternatively thereto, step 11 can include applying or depositing an intermediate layer 215, for example as described in relation to FIG. 1 to FIG. 5, onto the first layer 110, and applying or depositing the second layer 120 onto the intermediate layer 215. Furthermore, step 11 can include applying or depositing the third layer 130 onto the second layer. Alternatively thereto, step 11 can include applying or depositing an insulation layer 250 and/or a fourth layer 240 onto the second layer 120, and applying or depositing the third layer 130 onto the insulation layer 250 or the fourth layer 240, in a corresponding manner. Step 11 can take place in such a way that the intermediate layer 215, the fourth layer 240 and the insulation layer 250 fulfil the properties and the arrangement as described with respect to FIG. 1 to 5.

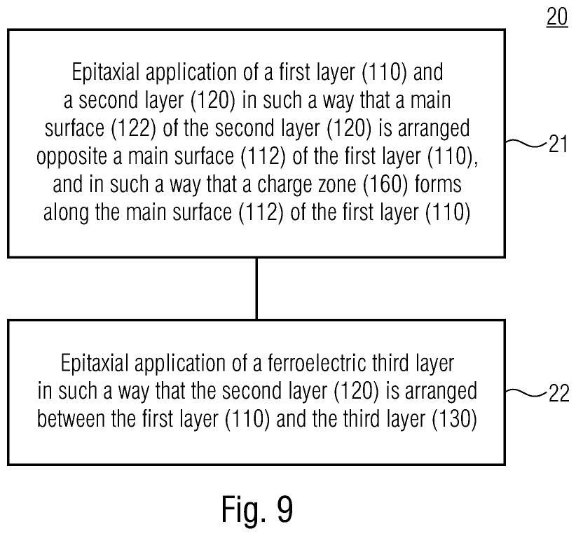

In examples of the method 10, step 11 can take place by means of the method 20 described with reference to FIG. 9.

FIG. 9 is a flow diagram of a method 20 for producing the HEMT according to one embodiment. The method 20 include a step 21 which comprises epitaxial application of a first layer 110 and a second layer 120. Step 21 takes place in such a way that a main surface 122 of the second layer 120 is arranged opposite a main surface 112 of the first layer 110. Furthermore, step 21 takes place such that a charge zone 160 forms along the main surface 112 of the first layer 110. This can be achieved by a selection of the materials of the first layer 110 and the second layer 120, as described in view of FIG. 1 to FIG. 5. Furthermore, the method 20 includes a step 22 which comprises epitaxial application of a ferroelectric third layer 130. Step 22 takes place in such a way that the second layer 120 is arranged between the first layer 110 and the third layer 130. Step 21 and step 20 take place in such a way that the first layer 110 comprises a first material 111 having a wurtzite crystal structure, the second layer 120 comprises second material 121 having a wurtzite crystal structure, and the third layer 130 comprises a ferroelectric third material 131 having a wurtzite crystal structure. As a result, the layer structure comprising the first layer 110, the second layer 120 and the third layer 130 can be epitaxially deposited particularly well.

The method 20 can include applying the first layer 110, the second layer 120, the third layer 130 in such a way that these are arranged as described with respect to FIG. 1 to 5. In particular, the first layer 110, the second layer 120, the third layer 130 can comprise the materials as described with respect to FIG. 1 to 5.

In examples, the method 20 includes depositing the first layer 110, the second layer 120, the third layer 120, as with respect to step 11 of the method 10. The method 20 can further include deposition of one or more of the intermediate layer 215, the fourth layer 240 and the insulation layer 250, as described with reference to step 11 of method 10, wherein the deposition of the respective layers takes place epitaxially. In these examples, advantageously all the layers mentioned with respect to step 11 can have a wurtzite crystal structure.

In particular, the method 10 from FIG. 8 and the method 20 from FIG. 9 can be carried out in such a way that the first layer 110 comprises the first material 111, the second layer 120 comprises the second material 121, and the third layer 130 comprises the third material 131, as described with respect to FIG. 1 to 5. For example, the combination of the first material 111 and the second material 121 can be one of AlGaN/GaN, AlScN/GaN, AlN/GaN and AlScN/GaScN. The third material can be a nitride compound or made of an oxide compound which comprises zinc. The third material can comprise one or more group III elements, for example one or more of Al, Ga, or In. Furthermore, the third material 131 can comprise a transition metal, e.g. Sc, Nb, Ti or Y. For example, the third material 131 can comprise one or more group III elements and a transition metal, wherein the fractions can optionally be selected as described with reference to FIG. 1. For the event that the method 10, 20 includes depositing the fourth layer 240, this can be carried out in such a way that the fourth layer comprises an electrically conductive material, for example one of TiN, NbN, Pt, Al, Ti, Ni, and Mo. Furthermore, the fourth layer can also be deposited epitaxially. For the event that the method 10, 20 includes depositing the intermediate layer 215, this can be carried out in such a way that the intermediate layer 215 comprises a material made of a nitride compound, for example one of AlN and GaN.

Although some aspects of the present disclosure have been described as features in connection with a device, it is clear that such a description can also be considered a description of corresponding method features. Although some aspects have been described as features in connection with a method, it is clear that such a description can also be considered a description of corresponding features of a device or of the functionality of a device.

In the detailed description above, sometimes different features have been grouped together into examples, in order to rationalize the disclosure. This type of disclosure is not intended to be interpreted as an intention for the claimed examples to comprise more features than explicitly specified in each claim. Rather, as follows from the following claims, the subject matter can be made in fewer than all the features of a single disclosed example. Consequently, the following claims are hereby incorporated into the detail description, wherein every claim can be an individual, separate example. While each claim can be an individual, separate example, it is noted that, although dependent claims in the claims refer back to a specific combination with one or more other claims, other examples also comprise a combination of dependent claims with the subject matter of each other dependent claim or a combination of each feature with other dependent or independent claims. Such combinations are included, unless it is stated that a specific combination is not intended. Furthermore, it is intended that a combination of features of one claim with any other independent claim is also included, even if said claim is not directly dependent on the independent claim.

The embodiments described above merely represent illustrations of the principles of the present disclosure. Of course, modifications and variations of the arrangements and details described herein are clear to other persons skilled in the art. It is therefore intended that the disclosure should be limited merely by the scope of protection of the below claims, and not by the specific details which were presented herein on the basis of the description and the explanation of the embodiments.

### REFERENCES

[Hao12] L. Z. Hao, J. Zhu, Y. J. Liu, X. W. Liao, S. L. Wang, J. J. Zhou, C. Kong, H. Z. Zeng, Y. Zhang, W. L. Zhang, Y. R. Li, Normally-off characteristics of LiNbO3/AlGaN/GaN ferroelectric field-effect transistor, Thin Solid Films, 520 (2012) 6313-6317
[Zhu18] Jiejie Zhu, Lixiang Chen, Jie Jiang, Xiaoli Lu, Ling Yang, Bin Hou, Min Liao, Yichun Zhou, Xiaohua Ma, and Yue Hao, Ferroelectric Gate AlGaN/GaN E-Mode HEMTs With High Transport and Sub-Threshold Performance, IEEE Electron Device Letters, 39 (2018) 79-82
[Li19] Guanjie Li, Xiaomin Li, Junliang Zhao, Qiuxiang Zhu and Yongbo Chen, Strong interfacial coupling effects of ferroelectric polarization with two-dimensional electron gas in BaTiO3/MgO/AlGaN/GaN/Si heterostructures, Journal of Materials Chemistry C, 7 (2019) 5677-5685
[Hao17] Yue Hao; Lixiang Chen; Xiaohua Ma; Jiejie Zhu; Jielong Liu, Doped HfO2 ferroelectric gate dielectric-based AlGaN/GaN enhancement mode HEMT (high electron mobility transistor) device and manufacturing method therefor; CN107316901A, 3 Nov. 2017
[Yan17] Ling Yang; Lixiang Chen; Xiaohua Ma; Jiejie Zhu; Jielong Liu, Stack gate enhanced GaN high-electron-mobility transistor containing ferroelectric gate dielectric and preparation method; CN107369704 A, 21 Nov. 2017
[Teo19] Koon Hoo Teo, Nadim Chowdhury, High electron mobility transistor with negative capacitor gate; US 2019/0115445 A1 (Apr. 18, 2019)
[Fic19] Simon Fichtner, Niklas Wolff, Fabian Lofink, Lorenz Kienle, Bernhard Wagner, AlScN: A III-V semiconductor based ferroelectric, Journal of Applied Physics, 125 (2019) 114103

1. A High-Electron-Mobility-Transistor, HEMT, comprising:
a first layer which comprises a first material made of a first nitride compound, wherein the first nitride compound comprises a group III element,
a second layer which comprises a second material made of a second nitride compound, wherein the second nitride compound comprises a group III element,
wherein a main surface of the second layer is arranged opposite a main surface of the first layer such that a charge zone forms along the main surface of the first layer, which provides a conduction channel in an enabled state of the HEMT,
a gate electrode, which is arranged opposite the second layer, at least in regions, such that the second layer is arranged between the first layer and the gate electrode,
a third layer, which is arranged between the gate electrode and the second layer, wherein the third layer comprises a ferroelectric third material made of a third nitride compound, or a ferroelectric third material made of an oxide compound which comprises zinc, the third material comprising a transition metal.

2. The HEMT according to claim 1, wherein the first material comprises a wurtzite crystal structure, and wherein the second material comprises a wurtzite crystal structure, and/or
wherein the third material comprises a wurtzite crystal structure.

3. The HEMT according to claim 2, wherein a coercivity of the third material is less than a coercivity of the second material.

4. The HEMT according to claim 1, wherein a proportion of the transition metal in the third layer is higher than a proportion of a transition metal in the second layer.

5. The HEMT according to claim 1, wherein the third material comprises a tensile stress.

6. The HEMT according to claim 1, wherein the transition metal is Sc, Nb, Ti or Y.

7. The HEMT according to claim 1, wherein the third material is made of the third nitride compound, and the third nitride compound comprises one or more group Ill elements, and wherein a stoichiometric proportion of the transition metal in the third material is between 10% and 50% of a total stoichiometric proportion of the one or more group III elements and the transition metal in the third material, or
wherein the third material is made of the oxide compound, and wherein a stoichiometric proportion of the transition metal in the third material is between 10% and 50% of a total stoichiometric proportion of the zinc and the transition metal in the third material.

8. The HEMT according to claim 1, wherein the gate electrode and the third layer are part of a gate structure which is arranged so as to be opposite the second layer, in regions.

9. The HEMT according to claim 1, further comprising a fourth layer which is arranged between the second layer and the third layer, wherein the fourth layer comprises an electrically conductive material.

10. The HEMT according to claim 9, wherein a capacitance between the fourth layer and the charge zone is greater than a capacitance between the fourth layer and the gate electrode.

11. The HEMT according to claim 1, further comprising an insulation layer which is arranged between the second layer and the third layer or between the second layer and the fourth layer, wherein the insulation layer comprises an electrically conductive material.

12. The HEMT according to claim 1, wherein the combination of the first material and the second material is one of AlGaN/GaN, AlScN/GaN, AlN/GaN and AlScN/GaScN.

13. The HEMT according to claim 1, wherein a polarization state of the third material can be set by applying a voltage to the gate electrode, and wherein a threshold voltage of the HEMT, at which a conduction channel through the charge zone changes between an enabled state and a disabled state, is dependent on the polarization state of the third material.

14. The HEMT according to claim 13, wherein the third material comprises a first polarization state, wherein the threshold voltage is positive when the third material is in the first polarization state and/or wherein the third material comprises a second polarization state, wherein the threshold voltage is negative when the third material is in the second polarization state.

15. The HEMT according to claim 13, wherein the gate electrode is arranged in a gate electrode region such that the polarization state of the third material in a first region of the third layer, opposite the gate electrode region, can be set by applying a voltage to the gate electrode, wherein the third layer further comprises a second region that is different from the first region, and
wherein the third material of the second region of the third layer is in a polarization state for which a charge zone region of the charge zone that is opposite the second region is in a conductive state.

16. A transistor assembly, comprising the HEMT according to claim 1, and further comprising a control signal generator, wherein the control signal generator is configured to apply a voltage to the gate electrode in order to set a polarization direction in a region of the third layer that is opposite the gate electrode.

17. The transistor assembly according to claim 16, wherein the control signal generator is configured to set a degree of polarization in the region of the third layer that is opposite the gate electrode by means of applying the voltage to the gate electrode in order to set a threshold voltage of the HEMT.

18. A method for controlling the HEMT according to claim 1, comprising:
applying a voltage to the gate electrode in order to set a polarization direction and/or a degree of polarization of the third material, in order to set a threshold voltage of the HEMT, at which a conduction channel through the charge zone changes between an enabled state and a disabled state.

19. The method according to claim 18, wherein setting the polarization direction and/or the degree of polarization of the third material takes place such that a threshold voltage of the HEMT, at which a conduction channel through the charge zone changes between an enabled state and a disabled state, is positive.

20. A method for producing an HEMT, comprising:
providing a layer structure comprising a first layer, a second layer, and a third layer, which comprises a ferroelectric third material made of a third nitride compound, or comprises a ferroelectric third material made of an oxide compound, which comprises zinc, comprises a third nitride compound, or a ferroelectric third material made of an oxide compound, which comprises zinc, the third material comprising a transition metal, such that
the second layer is arranged between the first layer and the third layer,
a main surface of the second layer is arranged opposite a main surface of the first layer, and
a charge zone forms along the main surface of the first layer, which provides a conduction channel in an enabled state of the HEMT,
applying a source contact and a drain contact in such a way that the charge zone is arranged electrically in series between the source contact and the drain contact,
temperature treatment of the layer structure together with the source contact and the drain contact.
